(19) United States
(12) Patent Application Publication
(10) Pub. No.: US 2022/0216485 A1
(43) Pub. Date: Jul. 7, 2022

(54) Power generation and energy storage in thermal batteries

(71) Applicant: Alexander Charles Kurple, Casco, MI (US)

(72) Inventor: Alexander Charles Kurple, Casco, MI (US)

(21) Appl. No.: 17/142,201

(22) Filed: Jan. 5, 2021

(51) Int. Cl. H01M 6/36; F28D 20/00

(52) U.S. Cl. CPC H01M 6/36; B60H 2001/2275; F28D 20/003

(57) ABSTRACT

The thermal batteries improves the operation of electrical equipment by storing energy in thermal materials and changing it to power instead of storing it in chemical energy and having to change the chemical energy to power the machine. The battery can use internal storage on one or both sides of the generator to power the the machine or can use the thermal energy in the environment to power the generator. The battery takes the energy from the high temperature storage on one side and moves it through the generator and sends the excess heat to the low temperature side. The high temperature sides can change to the low temperature side by moving the battery or changes to the operating environment of the machine. The battery extends its operation because it does not have energy limited by the size of the plates and can continue its operation and is charged by sending in new material at the necessary temperature or by increasing the temperature of the material in the battery to power the machine.

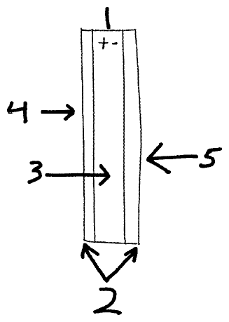

### BACKGROUND OF THE INVENTION

The invention seeks to improve the operation of electrical equipment by providing a power source utilizing excess heat from operation of an heat engine or the environment or energy sent in to avoid the use of expensive batteries and charging and increase the operation of the equipment.

### SUMMARY OF THE INVENTION

The process of generation power from a chemical energy source produces power to do the necessary work and excess heat that must be moved way from the generator to allow the process to continue. This invention takes the excess heat directly from the heat source or indirectly through heat in the environment to produce electrical power necessary for the operation on machines. The invention produces thermal batteries to generate power and store the energy to continue the operation.

### DESCRIPTION

The invention consists of an electrical connector shown in label 1 in drawing 1 and outer case in 2, the electricity generator 3, conductor storage 1 in 4, and conductor storage 2 in 5. The machine takes energy from one side to the other through the case and converts it to electricity in the electrical generator using thermoelectric plates, piezoelectric material, heat engine with generator attached, or turbogenerator powered by the difference in temperatures.

An example is taking the place of the battery in a telephone. The heat from the person moves through the temperature gradient between them and the outside environment do produce electricity in the thermoelectric plates or generator and power the telephone. The second claim would add storage like an ice pack to one side to increase the production. In the third claim circulating water or external higher voltage power would connected to change the battery to a plug to allow for continuous operation. The mode could be used to power portable equipment in continuous operation without having to change batteries.

1. A machine that takes heat energy from the higher temperature side moves it through a electrical generator to power the operation of a second machine or equipment and sends the excess heat to the colder side of the machine.

2. The machine in claim 1 and adds in an energy storage on one or both sides to control the transfer of energy from on side to the other. The energy storage can be done with high heat capacity solids, liquids, or gases, chemical reaction, pressure change, or phase change.

3. The machine in claim 1 with energy storage added an direct connections to a second energy source to increase the power output of the electrical generator when necessary by increasing the moving of energy carrying material, by electrical current, light, or other energy movement.
